(19) United States
(12) Patent Application Publication
(10) Pub. No.: US 2018/0025965 A1
(43) Pub. Date: Jan. 25, 2018

(54) WFCQFN (Very-Very Thin Flip Chip Quad Flat No Lead) with Embedded Component on Leadframe and Method Therefor

(71) Applicant: Dialog Semiconductor (UK) Limited, London (GB)

(72) Inventors: Baltazar Canete, JR., Waiblingen (DE); Melvin Martin, Stuttgart (DE); Ian Kent, Chippenham (GB); Jesus Mennen Belonio, JR., Neubiberg (DE); Rajesh Subraya Aiyandra, Ostfildern (DE)

(21) Appl. No.: 15/213,559

(22) Filed: Jul. 19, 2016

(51) Int. Cl. H01L 23/495; H01L 23/367; H01L 25/065; H01L 21/56; H01L 25/00; H01L 25/18; H01L 23/00; H01L 21/48

(52) U.S. Cl. CPC H01L 23/49575; H01L 23/49503; H01L 23/49541; H01L 24/17; H01L 23/3675; H01L 24/11; H01L 23/4952; H01L 21/4825; H01L 21/563; H01L 25/50; H01L 24/81; H01L 21/565; H01L 21/4828; H01L 25/18; H01L 25/0657; H01L 25/0652; H01L 21/4842; H01L 2224/13147; H01L 2924/14; H01L 2924/19011; H01L 2924/19102; H01L 2924/17747; H01L 2225/06517; H01L 2225/06513; H01L 2225/06589; H01L 2224/16145; H01L 2224/81193

(57) ABSTRACT

A quad flat no lead package is provided comprising at least one first integrated circuit die embedded in a recess in a die paddle of a metal leadframe and a second integrated circuit chip die attached to the at least one first integrated circuit die wherein the first and second integrated circuit dies are electrically connected to each other and wherein the second integrated circuit die is connected to leads of the leadframe through copper pillars.

### (1) TECHNICAL FIELD

This disclosure is related to flip chip quad flat no lead packages, and more particularly, to methods of flip chip attachment in quad flat no lead packages using an embedded component for very thin packages.

### (2) BACKGROUND

Quad Flat No-lead (QFN) packages are leadframe based packages that are becoming more widely used. This well known package has several advantages including a smaller footprint which is almost chip scale, reduced lead inductance, thin profile, and low weight. The leads at the periphery of the package are ideal for better printed circuit board (PCB) routing. Thermal and electrical performance are also enhanced by the exposed copper die paddle underneath the leadframe which is directly connected to the PCB. QFN packages are a common choice in the industry for optimal size, weight, and thermal and electrical performance.

U.S. Pat. No. 9,136,256 (Joshi) and U.S. Pat. No. 9,184,121 (Lopez et al) and U.S. Patent Application 2009/0309198 (Lee et al) discuss chips placed in recesses of a leadframe, but these packages are different from those in the present disclosure.

### SUMMARY

It is the primary objective of the present disclosure to provide an extremely thin flip chip quad flat no lead package.

Yet another objective is to provide an extremely thin flip chip quad flat no lead package having a chip embedded in a recess in the leadframe die paddle.

A further objective is to provide an extremely thin flip chip quad flat no lead package without wire bonds.

In accordance with the objectives of the present disclosure, an extremely thin flip chip quad flat no lead package is achieved. At least one first integrated circuit die is embedded in a recess in a die paddle of a metal leadframe. A second integrated circuit die is attached to the at least one first integrated circuit die wherein the first and second integrated circuit dies are electrically connected to each other and wherein the second integrated circuit die is connected to leads of the leadframe through copper pillars.

Also in accordance with the objectives of the present disclosure, a method of forming an extremely thin flip chip quad flat no lead package is achieved. A leadframe is provided having at least one recess formed in a top surface of a die paddle portion of the leadframe. At least one first integrated circuit die is embedded in the at least one recess. Solder bumps are formed on the at least one first integrated circuit die. Copper pillars are formed on the die paddle portion and on leads of the leadframe. An underfill material is coated on the die paddle portion of the leadframe surrounding the solder bumps and copper pillars. Thereafter a second integrated circuit die is flip chip attached to the at least one first integrated circuit die, wherein the first and second integrated circuit dies are electrically connected through the solder bumps and wherein the second integrated circuit die is electrically connected to the die paddle portion of the leadframe and to the leads through the copper pillars. The package is thereafter encapsulated with a molding compound wherein a top surface of the second integrated circuit die is exposed to complete the quad flat no lead package.

### BRIEF DESCRIPTION OF THE DRAWINGS

In the accompanying drawings forming a material part of this description, there is shown:

FIG. 1A is a top view of a leadframe having a cavity therein.

FIG. 1B is a cross-sectional representation across B-B′ of the leadframe in FIG. 1A, having the cavity therein, in a first step of a preferred embodiment of the present disclosure.

FIG. 2 is a cross-sectional representation of a second step of a preferred embodiment of the present disclosure.

FIG. 3A is a top view of a leadframe after a third step of a preferred embodiment of the present disclosure.

FIG. 3B is a cross-sectional representation of the third step of a preferred embodiment of the present disclosure.

FIG. 4A is a top view of a leadframe after a fourth step of a preferred embodiment of the present disclosure.

FIG. 4B is a cross-sectional representation of the fourth step of a preferred embodiment of the present disclosure.

FIG. 5A is a cut away top view of a leadframe after a fifth step of a preferred embodiment of the present disclosure.

FIG. 5B is a cross-sectional representation of the fifth step of a preferred embodiment of the present disclosure.

FIG. 6 is a cross-sectional representation of a final step of a preferred embodiment of the present disclosure.

### DETAILED DESCRIPTION

The present disclosure presents a process of manufacturing an extremely thin quad flat no lead (QFN) package using Flip Chip technology and embedding optionally multiple chips on the metal frame. The chips are connected via copper pillar bumps, thus eliminating bonding wires. An exposed die on top of the package not only helps minimize the package profile, but also helps dissipate more heat easily, resulting in excellent junction-to-case thermal resistance.

The standard QFN is a leadframe-type package where a chip (or a die) is mounted to the die paddle via a die attach glue. The electrical flow is via bonding wires which are connected from the die bonding pads to the package leads. The package is finally encapsulated by an Epoxy Mould Compound (EMC) for mechanical protection and mechanical integrity.

The extremely thin QFN package of the present disclosure will be described in detail with reference to the drawing figures.

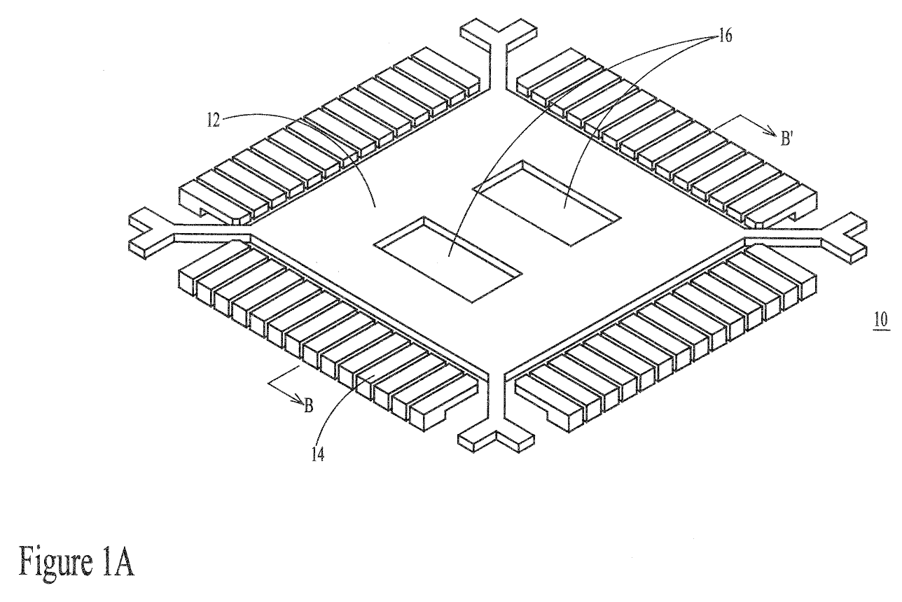

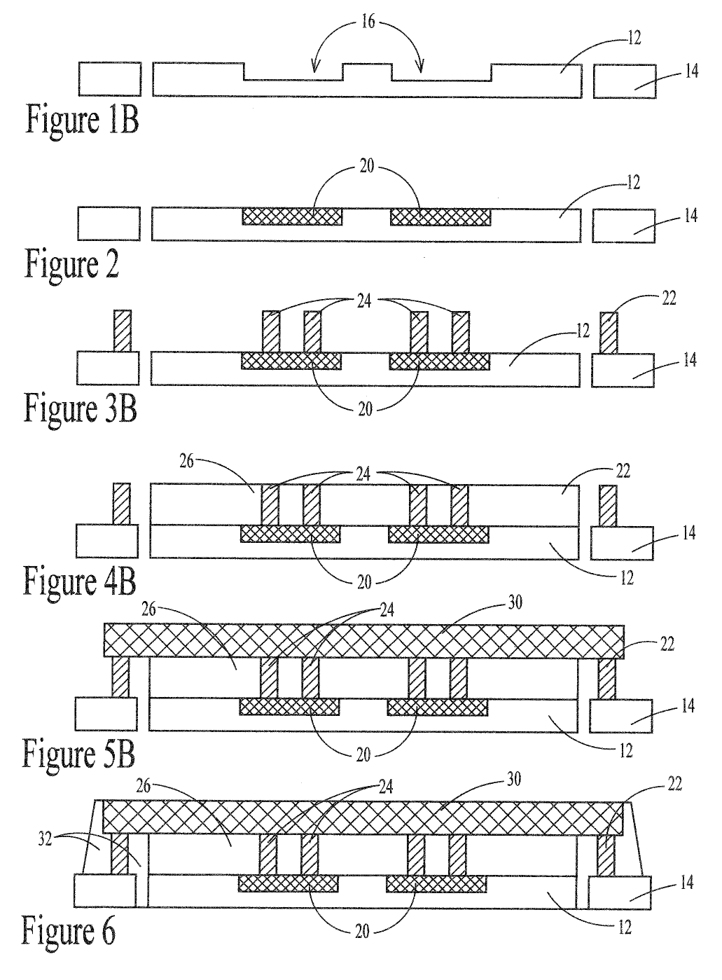

An essential feature of the present disclosure is the half-etching on the top surface of the leadframe to accommodate one or more additional dies. FIG. 1A illustrates a top view of the leadframe 10, showing the die paddle 12 and leads 14. Cavities 16 are formed on the top surface of the die paddle 12. Preferrably, the cavities are formed by half-etching (wet and/or dry etching). This is a method where a defined surface of the leadframe is exposed and the exposed area is etched away to a certain depth to form a cavity. Preferably, half-etching is performed during the manufacturing of the leadframe. Preferably, a chemical etching is used to form the cavity 16. Alternatively, other methods could be used such as stamping, laser drilling, or dry etching. One or more cavities could be formed. Two cavities 16 are illustrated in the drawings. FIG. 1B illustrates cavities 16 in cross-section B-B′.

The cavities 16 can be etched to any depth appropriate for the dies to be embedded into the cavities. Chemical etching parameters can be adjusted to form cavities to the desired depth.

Referring now to FIG. 2, the dies 20 are embedded into the cavities 16 and attached using a die-attach glue, such as epoxy. Alternatively, underfill could be used to embed the dies into the cavities, but die-attach glue is preferred.

For example, the dies could be integrated passive devices (IPD). However, any kind of integrated circuit devices could be embedded into the cavities.

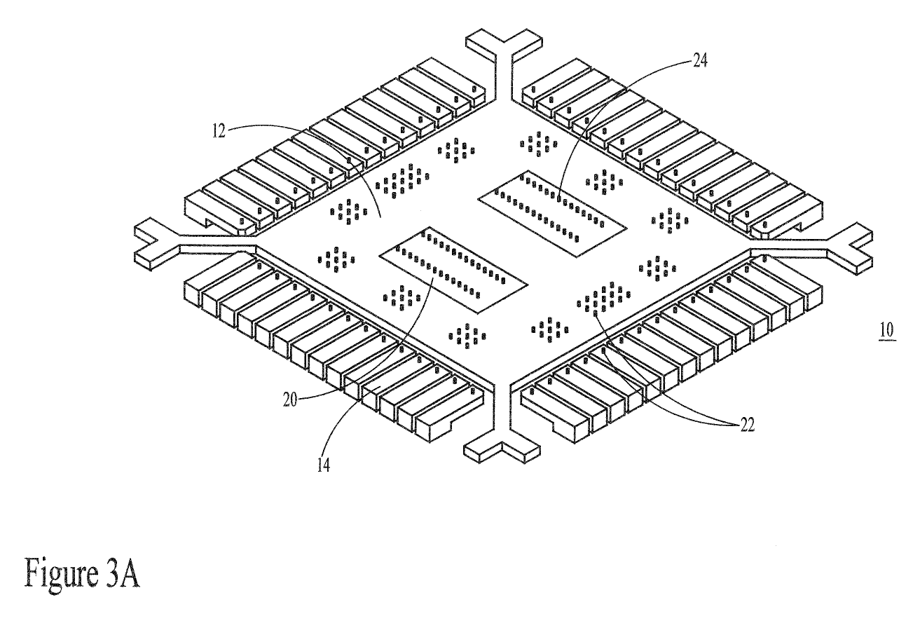

Now, as shown in FIGS. 3A and 3B, copper pillars 22 are formed on the die paddle and on the leads (FIG. 3A). Preferably, solder bumps 24 are placed on the embedded dies.

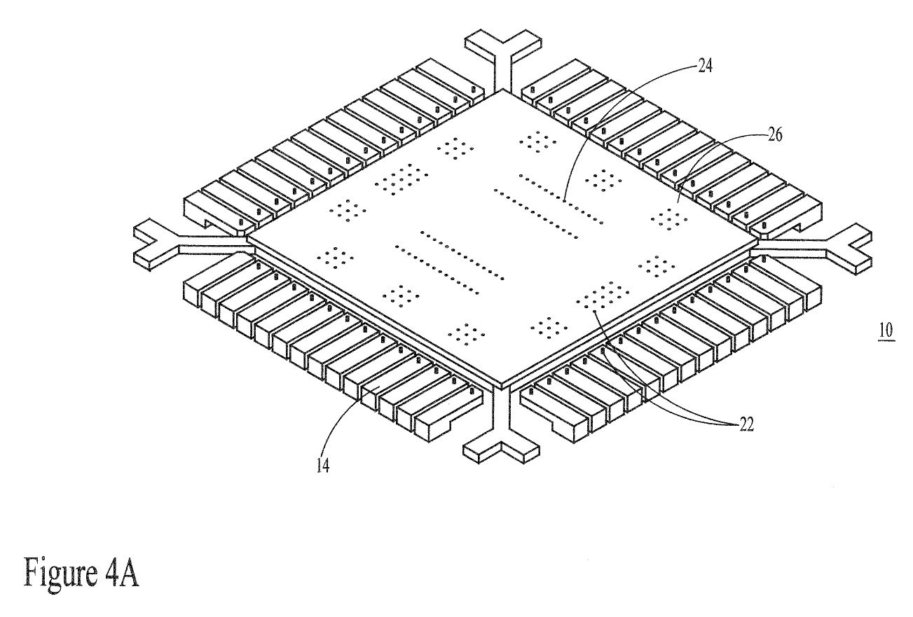

An underfill 26 is dispensed and flows via capillary action onto the die paddle area 12 as shown in FIGS. 4A and 4B. The underfill provides mechanical stability and reliability. The embedding of at least one die will allow the package to have more complexity without compromising the total size and thickness.

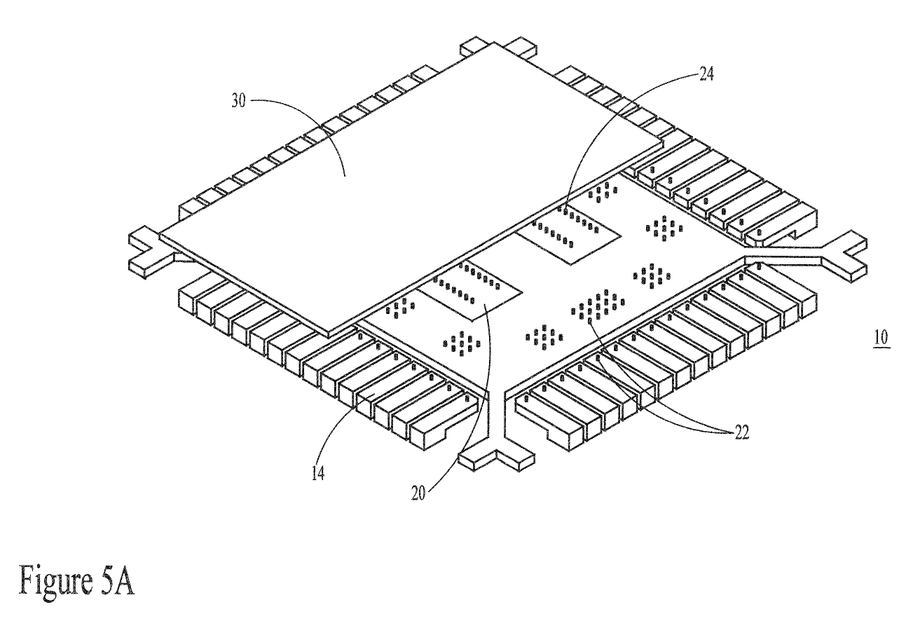

Now, a mother die 30 is attached to the embedded dies 20 in a flip chip process, as shown in FIG. 5B. FIG. 5A is a top view, half cutaway and with the underfill not shown. The embedded chips 20 can be seen under the mother die 30. Signals flow from the mother die 30 to the IPD or other embedded dies 20, and vice versa, through solder bumps 24. The mother die is connected to the leads through copper pillars 22.

The completed package is shown in cross section in FIG. 6 after encapsulation with an epoxy molding compound 32. The external package outline looks similar to that of a standard QFN except for the exposed top surface of the mother die 30. The exposed die on top of the package, although not required, not only helps minimize the package profile, but also helps dissipate more heat easily, resulting in excellent junction-to-case thermal resistance.

Embedding the integrated passive or other dies in the recesses in the leadframe allows an increase in die thickness without increasing the overall package thickness. The package design of the present disclosure will save space on application boards and also reduce the number of devices that need to be soldered to such boards. This facilitates routing on the boards, reduces board size, and makes the boards less expensive. This package design enhances package performance for complex applications and allows multiple chips without compromising the total package height.

The thinner package profile will be ideal for mobile applications where space is limited. The package of the present disclosure is an ideal alternative for packages with high complexity and application features without hampering the external package outline. The package of the present disclosure allows for higher levels of integration without requiring more space.

Although the preferred embodiment of the present disclosure has been illustrated, and that form has been described in detail, it will be readily understood by those skilled in the art that various modifications may be made therein without departing from the spirit of the disclosure or from the scope of the appended claims.

What is claimed is:

1. A quad flat no lead package comprising:
at least one first integrated circuit die embedded in a recess in a die paddle portion of a metal leadframe; and
a second integrated circuit die attached to said at least one first integrated circuit die wherein said first and second integrated circuit dies are electrically connected to each other and wherein said second integrated circuit die is connected to leads of said leadframe through copper pillars.

2. The package according to claim 1 wherein said at least one first integrated circuit die is an integrated passive device and wherein said second integrated circuit die is a mother die.

3. The package according to claim 1 wherein said first and second integrated circuit dies are electrically connected to each other through solder bumps.

4. The package according to claim 1 wherein said package contains no wire bonds.

5. The package according to claim 1 wherein a top surface of said second integrated circuit is exposed to minimize the package profile and to dissipate heat.

6. A method of fabricating a quad flat no lead package comprising:
providing a leadframe having at least one recess formed in a top surface of a die paddle portion of said leadframe;
embedding at least one first integrated circuit die in said at least one recess;
forming solder bumps on said at least one first integrated circuit die;
forming copper pillars on said leadframe and on leads of said leadframe;
dispensing an underfill material surrounding said solder bumps and said copper pillars on said die paddle portion of said leadframe; and
thereafter flip chip attaching a second integrated circuit die to said at least one first integrated circuit die, wherein said first and second integrated circuit dies are electrically connected through said solder bumps and wherein said second integrated circuit die is electrically connected to said die paddle portion of said leadframe and to said leads through said copper pillars and wherein a thickness of said at least one first integrated circuit die does not contribute to a thickness of completed said quad flat no lead package.

7. The method according to claim 6 further comprising encapsulating said package with a molding compound wherein a top surface of said second integrated circuit die is exposed to complete said quad flat no lead package.

8. The method according to claim 6 wherein said at least one first integrated circuit die is an integrated passive device and wherein said second integrated circuit die is a mother die.

9. The method according to claim 6 wherein said package contains no wire bonds.

10. The method according to claim 6 wherein said at least one recess in said die paddle portion of said leadframe is formed by chemical etching or by a combination of wet and dry etching.

11. The method according to claim 6 wherein said at least one recess in said die paddle portion of said leadframe is formed by stamping, laser drilling, or dry etching.

12. The method according to claim 6 wherein there are two or more first integrated circuit dies embedded, each first integrated circuit die embedded in its own recess in said die paddle portion of said leadframe.

13. A quad flat no lead package comprising:
at least one first integrated circuit die embedded in a recess in a top surface of a die paddle portion of a metal leadframe; and
a second integrated circuit die attached to said at least one first integrated circuit die wherein said first and second integrated circuit dies are electrically connected to each other and wherein said second integrated circuit die is connected to leads of said leadframe through copper pillars and wherein a thickness of said at least one first integrated circuit die does not contribute to a thickness of completed said quad flat no lead package.

14. The package according to claim 13 wherein said at least one first integrated circuit die is an integrated passive device and wherein said second integrated circuit die is a mother die.

15. The package according to claim 13 wherein said first and second integrated circuit dies are electrically connected to each other through solder bumps.

16. The package according to claim 13 wherein said package contains no wire bonds.

17. The package according to claim 13 wherein a top surface of said second integrated circuit is exposed to minimize the package profile and to dissipate heat.
